(19) United States
(12) Patent Application Publication
(10) Pub. No.: US 2025/0273577 A1
(43) Pub. Date: Aug. 28, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Jaeyoung CHOI, Suwon-si (KR); Youngchan KO, Suwon-si (KR); Byungho KIM, Suwon-si (KR); Wooseok PARK, Suwon-si (KR); Yongkoon LEE, Suwon-si (KR); Myungdo CHO, Suwon-si (KR); Hyeokjin CHU, Suwon-si (KR)

(73) Assignee: Samsung Electronics Co., Ltd., Suwon-si (KR)

(21) Appl. No.: 18/978,637

(22) Filed: Dec. 12, 2024

(30) Foreign Application Priority Data
Feb. 28, 2024 (KR) 10-2024-0028522

(51) Int. Cl. H01L 23/538; H01L 21/48; H01L 21/56; H01L 23/00; H01L 23/14; H01L 23/31; H01L 23/498; H01L 25/18; H10B 80/00

(52) U.S. Cl. CPC H01L 23/5381; H01L 23/147; H01L 23/49833; H01L 23/49838; H01L 24/16; H01L 21/4853; H01L 21/56; H01L 23/3185; H01L 24/32; H01L 24/73; H01L 25/18; H01L 2224/16145; H01L 2224/16227; H01L 2224/16238; H01L 2224/32225; H01L 2224/73204; H01L 2224/73253; H01L 2225/06513; H01L 2225/06517; H01L 2924/1431; H01L 2924/14361; H10B 80/00

(57) ABSTRACT

A semiconductor package includes a lower redistribution wiring layer, a bridge chip provided on the lower redistribution wiring layer and having a bump structure, a sealing member covering the bridge chip on the lower redistribution wiring layer, a plurality of vertical conductive structures around the bridge chip and penetrating the sealing member, an upper redistribution wiring layer disposed on the sealing member, a first semiconductor device mounted on the upper redistribution wiring layer, and a second semiconductor device mounted on the upper redistribution wiring layer and spaced apart from the first semiconductor device, the second semiconductor device being electrically connected to the first semiconductor device by the bridge chip.

### CROSS-REFERENCE TO RELATED APPLICATIONS

This application claims priority under 35 U.S.C. § 119 to Korean Patent Application No. 10-2024-0028522, filed on Feb. 28, 2024 in the Korean Intellectual Property Office (KIPO), the contents of which are herein incorporated by reference in their entirety.

### BACKGROUND

### 1. Field

Example embodiments relate to semiconductor packages and methods of manufacturing the semiconductor package. More particularly, example embodiments relate to semiconductor packages including a plurality of different chips mounted on a package substrate using an interposer and methods of manufacturing the same.

### 2. Description of the Related Art

In 2.xD packages such as 2.3D, a substrate structure such as an interposer may be used to provide high-density interconnections. A logic semiconductor device and a memory semiconductor device may be placed on the interposer and then may be molded using a molding material. Here, the logic semiconductor device and the memory semiconductor device may be electrically connected through a silicon bridge chip (Si-Bridge chip). There is a problem in that warpage occurs due to a difference in thermal expansion coefficient between individual components (e.g., a redistribution wiring layer) constituting the interposer and a semiconductor device mounted on the interposer.

### SUMMARY

Some example embodiments provide semiconductor packages having a structure that is able to eliminate imbalance in overall thermal expansion coefficients.

Some example embodiments provide methods of manufacturing the semiconductor package.

According to an example embodiment, a semiconductor package includes a lower redistribution wiring layer having lower redistribution wirings, a bridge chip being on the lower redistribution wiring layer, the bridge chip including a substrate and bridge chip pads, a bump structure being an upwardly protruding portion of the substrate, the bridge chip pads being around the bump structure on the substrate, a sealing member covering the bridge chip on the lower redistribution wiring layer, a plurality of vertical conductive structures being around the bridge chip, penetrating the sealing member, and electrically connected to the lower redistribution wirings, an upper redistribution wiring layer being on the sealing member, the upper redistribution wiring layer including upper redistribution wirings, the upper redistribution wirings being electrically connected to the plurality of vertical conductive structures and the bridge chip pads, a first semiconductor device mounted on the upper redistribution wiring layer, and a second semiconductor device mounted on the upper redistribution wiring layer and spaced apart from the first semiconductor device, the second semiconductor device being electrically connected to the first semiconductor device by the bridge chip.

According to an example embodiment, a semiconductor package includes an interposer including a lower redistribution wiring layer, a bridge chip, a plurality of vertical conductive structures, a sealing member, and an upper redistribution wiring layer, the bridge chip being on the lower redistribution wiring layer and including a substrate, the substrate having a bump structure in a middle region thereof, the bump structure being an upwardly protruding portion of the substrate, the plurality of vertical conductive structures being around the bridge chip on the lower redistribution wiring layer, the sealing member covering the bridge chip and the plurality of vertical conductive structures on the lower redistribution wiring layer, and the upper redistribution wiring layer being on the sealing member and including upper redistribution wirings, the upper redistribution wirings electrically connected to the plurality of vertical conductive structures and the bridge chip, a first semiconductor device mounted on the interposer and electrically connected to the bridge chip, and a second semiconductor device mounted on the interposer, spaced apart from the first semiconductor device, and electrically connected to the bridge chip.

According to an example embodiments, a semiconductor package includes a substrate structure including an upper surface and a lower surface opposite the upper surface, the substrate structure including a bridge chip therein, a first semiconductor device mounted on the substrate structure, and a second semiconductor device mounted on the substrate structure, spaced apart from the first semiconductor device, and electrically connected to the first semiconductor device by the bridge chip. The bridge chip includes a substrate having a middle region and a peripheral region surrounding the middle region, the substrate having in the middle region thereof, the bump structure being an upwardly protruding portion of the substrate, a wiring layer having a plurality of wirings on the peripheral region of the substrate, and bridge chip pads being on the wiring layer and electrically connected to the wirings.

According to an example embodiment, a semiconductor package may include a substrate structure having a bridge chip therein, a first semiconductor device mounted on the substrate structure, and a second semiconductor device mounted the substrate structure and spaced apart from the first semiconductor device. Because the substrate structure including a redistribution wiring layer has a greater thermal expansion coefficient than the first and second semiconductor devices, warpage may occur due to a mismatch in thermal expansion coefficient between the substrate structure and the semiconductor devices.

The bridge chip may have a convex bump structure in a middle region thereof. The middle region where the bump structure is formed may have a relatively thick silicon portion, thereby reducing the thermal expansion coefficient of the substrate structure. Accordingly, the bump structure may increase a space ratio (concentration) occupied by the silicon die portion to match the thermal expansion coefficient between upper and lower portions of the semiconductor package, to thereby reduce or prevent the warpage.

### BRIEF DESCRIPTION OF THE DRAWINGS

Example embodiments will be more clearly understood from the following detailed description taken in conjunction with the accompanying drawings. FIGS. 1 to 27 represent non-limiting, example embodiments as described herein.

FIG. 1 is a plan view illustrating a semiconductor package in accordance with an example embodiment.

FIG. 2 is an enlarged cross-sectional view illustrating portion ‘A’ in FIG. 1.

FIG. 3 is a plan view illustrating a bridge chip in a substrate structure in FIG. 1.

FIGS. 4 to 27 are views illustrating a method of manufacturing a semiconductor package in accordance with an example embodiment.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, some example embodiments will be explained in detail with reference to the accompanying drawings.

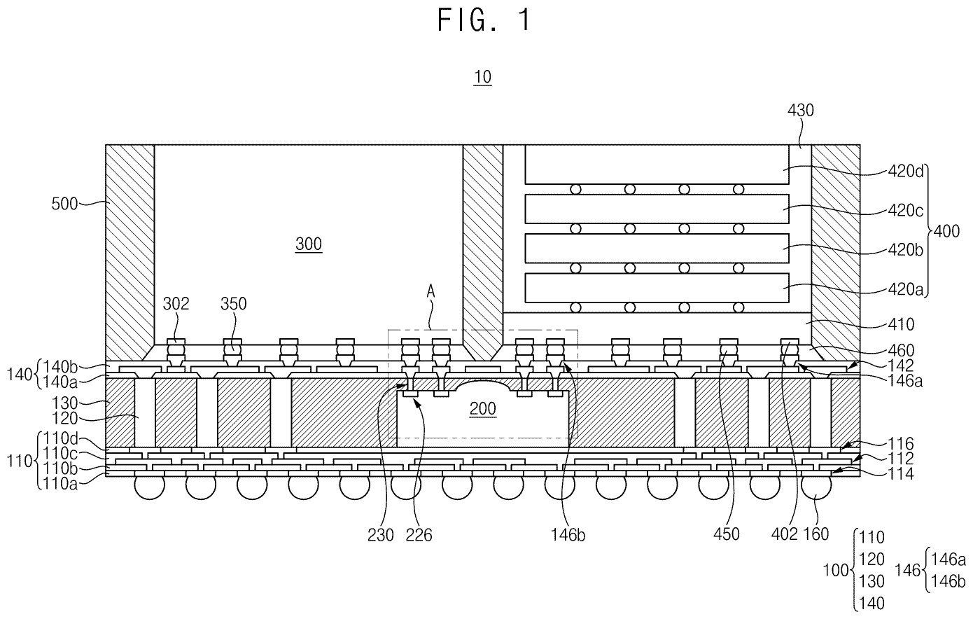

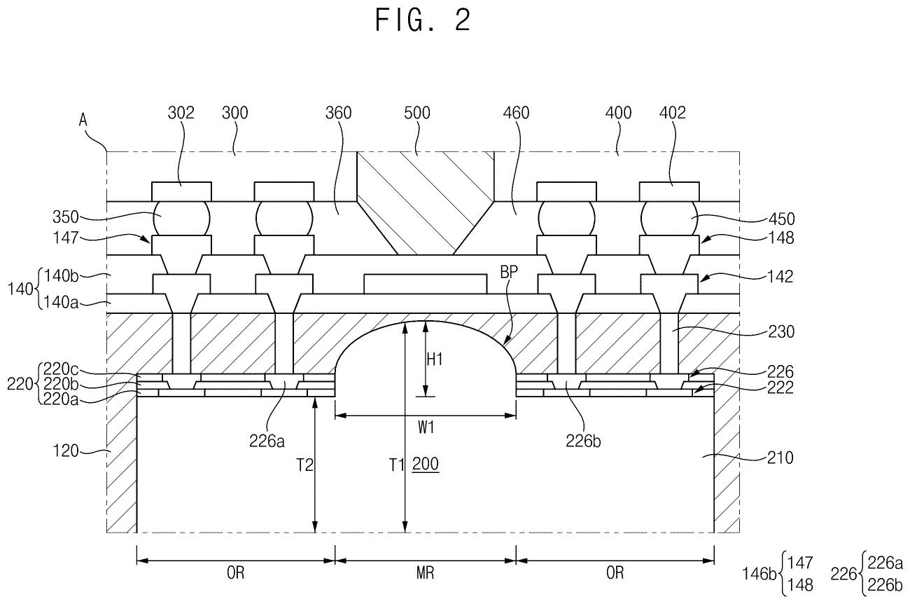

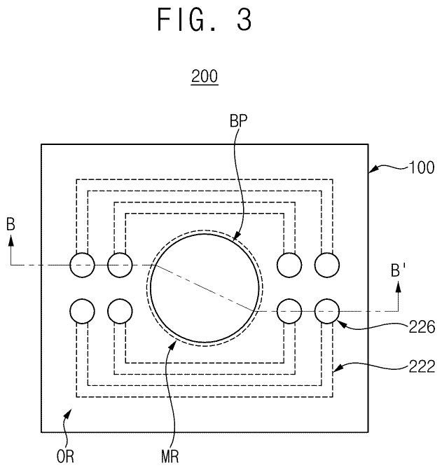

FIG. 1 is a plan view illustrating a semiconductor package in accordance with an example embodiment. FIG. 2 is an enlarged cross-sectional view illustrating portion ‘A’ in FIG. 1. FIG. 3 is a plan view illustrating a bridge chip in a substrate structure in FIG. 1. FIG. 2 includes a cross-sectional portion taken along the line A-A′ in FIG. 3.

Referring to FIGS. 1 to 3, a semiconductor package 10 may include a substrate structure 100 having at least one bridge chip 200, a first semiconductor device 300 mounted on the substrate structure 100, and a second semiconductor device 400 mounted on the substrate structure 100 and spaced apart from a first semiconductor device 300. In addition, the semiconductor package 10 further include a sealing member 500 that covers the first and second semiconductor devices 300 and 400 on the substrate structure 100 and external connection bumps 160 provided on a lower surface of the substrate structure 100.

In some example embodiments, the semiconductor package 10 may be a memory device having a stacked chip structure in which a plurality of dies (chips) are stacked. For example, the semiconductor package 10 may include a semiconductor memory device with a 2.xD chip structure such as 2.3D. In this case, the first semiconductor device 300 may include a logic semiconductor device, and the second semiconductor device 400 may include a memory device. The logic semiconductor device may be an ASIC as a host. such as CPU, GPU, or SoC. The memory device may include a high bandwidth memory (HBM) device, dynamic random access memory (DRAM), etc.

In some example embodiments, the substrate structure 100 may serve as an interposer that provides high-density interconnection between the first and second semiconductor devices 300 and 400. The substrate structure 100 may be a substrate having an upper surface and a lower surface opposite to the upper surface. The first semiconductor device 300 and the second semiconductor device 400 may be electrically connected to each other through wirings in the interposer.

The substrate structure 100 may include a lower redistribution wiring layer 110, a bridge chip 200 disposed on the lower redistribution wiring layer 110, and a plurality of vertical conductive structures 120 disposed around the bridge chip 200 on the lower redistribution wiring layer 110, a sealing member 130 covering the bridge chip 200 and the plurality of vertical conductive structures 120 on the lower redistribution wiring layer 110, and an upper redistribution wiring layer 140 provided on the sealing member 130.

The lower redistribution wiring layer 110 may include first, second, third and fourth lower insulating layers 110a, 110b, 110c, and 110d and lower redistribution wirings 112 within the first to fourth lower insulating layers. The first to fourth lower insulating layers may include a polymer, a dielectric layer, etc. For example, the first to fourth lower insulating layers may include a photosensitive insulating layer such as a photo imagable dielectric (PID). The lower redistribution wirings 122 may include aluminum (Al), copper (Cu), tin (Sn), nickel (Ni), gold (Au), platinum (Pt), or an alloy thereof.

A lower substrate pad 114 may be provided in the first lower insulating layer 110a. The lower substrate pad 114 may be a bump pad. The bump pad may include a solder pad or pillar pad. For example, the lower substrate pad 114 may include copper (Cu), aluminum (Al), tin (Sn), nickel (Ni), gold (Au), platinum (Pt), or an alloy thereof.

The second lower insulating layer 110b may be formed on the first lower insulating layer 110a, and the lower redistribution wiring 112 may be formed on the second lower insulating layer 110b. The lower redistribution wiring 112 may be electrically connected to the lower substrate pad 114 through a first opening formed in the second lower insulating layer 110b.

The third lower insulating layer 110c may be formed on the second lower insulating layer 110b, and an upper connection pad 116 may be formed on the third lower insulating layer 110c. The upper connection pad 116 may be electrically connected to the lower redistribution wiring 112 through a second opening formed in the third lower insulating layer 110c.

The fourth lower insulating layer 110d may be formed on the third lower insulating layer 110c and may expose portions of the upper connection pads 116. The upper connection pads 116 may be exposed from an upper surface of the lower redistribution wiring layer 110. For example, the upper connection pads 116 may have a multilayer structure. The upper connection pad 116 may include a bonding pad pattern and a plating pad pattern formed on the bonding pad pattern. The bonding pad pattern may include copper (Cu), and the plating pad pattern may include nickel (Ni), gold (Au), or titanium (Ti).

When viewed in plan view, the lower redistribution wiring layer 110 may include a first region that overlaps the bridge chip 200 and a second region as a connector region surrounding the first region. The upper connection pads 116 may be bonding pads for connection with a conductive structure, which are formed on the uppermost lower redistribution wirings 112 in the second region.

In this example embodiment, the lower redistribution wiring layer 110 is illustrated as having one layer of lower redistribution wirings 112, but is not limited thereto, and the lower redistribution wiring layer 112 may have lower redistribution wirings 112 stacked in at least two layers.

In some example embodiments, the bridge chip 200 may be disposed in the first region of the lower redistribution wiring layer 110. The bridge chip 200 may include a substrate 210, a wiring layer 220, and bridge chip pads 226. The bridge chip 200 may further include conductive pillars 230 provided on the bridge chip pads 226.

In some example embodiments, the plurality of vertical conductive structures 120 may be disposed in the second region on the lower redistribution wiring layer 110. The vertical conductive structures 120 may extend upward from the upper connection pads 116 of the lower redistribution wiring layer 110, respectively. For example, a diameter of the vertical conductive structure 120 may be within a range of about 20 μm to about 100 μm, and a length of the vertical conductive structure 120 may be within a range of about 50 μm to about 300 μm.

The sealing member 130 may cover the bridge chip 200 and the plurality of vertical conductive structures 120 on the upper surface of the lower redistribution wiring layer 110. The sealing member 130 may expose upper surfaces of the conductive pillars 230 of the bridge chip 200 and upper surfaces of the plurality of vertical conductive structures 120. For example, the sealing member 130 may include epoxy mold compound (EMC). The sealing member 130 may be formed by a molding process, a screen printing process, a lamination process, etc.

The sealing member 130 may include a first sealing portion that covers an upper surface of the bridge chip 200 and a second sealing portion that covers the upper surface of the lower redistribution wiring layer 110 around the bridge chip 200. The first sealing portion of the sealing member 130 on a convex dome-shaped bump structure BP may have a relatively thin thickness due to the bump structure BP.

The vertical conductive structure 120 may be provided to penetrate the sealing member 130 and may serve as an electrical connection path. The vertical conductive structure 120 may function as a through mold via (TMV) formed through the second sealing portion of the sealing member 130. That is, the vertical conductive structures 120 may be provided in the second region outside the area where the bridge chip 200 is disposed, and may electrically connect the lower redistribution wiring layer 110 and the upper redistribution wiring layer 140.

As illustrated in FIGS. 2 and 3, the substrate 210 may have a middle region MR and a peripheral region OR surrounding the middle region MR. The substrate 210 may have the bump structure BP that protrudes from an upper surface thereof in the center region MR. In other words, the bump structure may be an upwardly protruding portion of the substrate 210. The wiring layer 220 may have a plurality of wirings 222 in the peripheral region OR of the substrate 210. The bridge chip pads 226 may be provided on an upper surface of the wiring layer 220 and may be electrically connected to the wirings 222. The bridge chip pads 226 may include a first bridge chip pad 226a and a second bridge chip pad 226b that are disposed with the bump structure BP therebetween. The first bridge chip pad 226a and the second bridge chip pad 226b may be electrically connected to each other by the wiring 222. The conductive pillars 230 may be provided on the first bridge chip pad 226a and the second bridge chip pad 226b, respectively.

For example, the bump structure BP may have a desired (or alternatively, predetermined) height H1 from the upper surface of the substrate 210. The bump structure BP may have a desired (or alternatively, predetermined) width W1. The middle region MR of the substrate 210 may have a first thickness T1, and the peripheral region OR of the substrate 210 may have a second thickness T2. The first thickness T1 may be greater than the second thickness T2. The bump structure BP may have a dome shape. The bump structure BP may have a convex cross-sectional shape.

In this example embodiment, the bridge chip 200 includes the convex dome-shaped bump structure BP, but it is not limited to, and the bump structure protruding from the upper surface 212 of the substrate 210 may have a cylindrical shape, a square column shape, a truncated cone shape, a polygonal pyramid shape, etc. In the figures, one bridge chip is disposed, but the present inventive concepts are not limited thereto. For example, the same number of bridge chips as the number of the second semiconductor devices connected to the first semiconductor device may be disposed.

The bridge chip 200 accommodated in the sealing member 130 of the substrate structure 100 may include a silicon material and thus may have a relatively low coefficient of thermal expansion. The bump structure BP of the bridge chip 200 may have a first thermal expansion coefficient, and the sealing member 130 may have a second thermal expansion coefficient that is greater than the first thermal expansion coefficient.

In some example embodiments, the upper redistribution wiring layer 140 may be disposed on the sealing member 130. The upper redistribution wiring layer 140 may include first and second upper insulating layers 140a and 140b and upper redistribution wirings 142 within the first and second upper insulating layers 140a and 140b. The upper redistribution wirings 142 may be electrically connected to the vertical conductive structures 120 and the conductive pillars 230 of the bridge chip 200, respectively.

The first upper insulating layer 140a may be provided on the upper surface of the sealing member 130 and may have openings that expose upper end portions of the vertical conductive structures 120 and upper end portions of the conductive pillars 230. The upper redistribution wirings 142 may be provided on the first upper insulating layer 140a and may be electrically connected to the vertical conductive structures 120 and the conductive pillars 230 through the openings.

The second upper insulating layer 140b may be provided on the first upper insulating layer 140a and may have openings that expose the upper redistribution wirings 142. Upper substrate pads 146 may be provided on the second lower insulating layer 140b. The upper substrate pads 146 may be electrically connected to the upper redistribution wirings 142 through the openings formed in the second lower insulating layer 140b.

The upper substrate pads 146 may be exposed from an upper surface of the upper redistribution wiring layer 140. For example, the upper substrate pads 146 may have a multilayer structure. The upper substrate pad 146 may include a bonding pad pattern and a plating pad pattern formed on the bonding pad pattern. The bonding pad pattern may include copper (Cu), and the plating pad pattern may include nickel (Ni), gold (Au), or titanium (Ti).

In some example embodiments, the upper substrate pads 146 may include first upper bonding pads 146a and second upper bonding pads 146b. First pads among the first upper bonding pads 146a may be pads for connection with the first semiconductor device 300, and second pads among the first upper bonding pads 146a may be pads for connection with the second semiconductor device 400.

The second upper bonding pads 146b may include first bonding pads 147 and second bonding pads 148. The first bonding pads 147 may be pads for electrical connection between the first semiconductor device 300 and the bridge chip 200, and the second bonding pads 148 may be pads for electrical connection between the second semiconductor device 400 and the bridge chip 200. The first bonding pad 147 may be electrically connected to the first bridge chip pad 226a by the upper redistribution wiring 142 and the conductive pillar 230, and the second bonding pad 148 may be connected to the second bridge chip pad 226b by the upper redistribution wiring 142 and the conductive pillar 230. Accordingly, the first bonding pad 147 and the second bonding pad 148 may be electrically connected to each other by the upper redistribution wiring 142 and the bridge chip 200.

It will be understood that the number, size, and arrangement of the upper insulating layers and the upper redistribution wirings of the upper redistribution wiring layer are provided as examples, and the present inventive concepts are not limited thereto.

In some example embodiments, the first semiconductor device 300 and the second semiconductor device 400 may be mounted on the substrate structure 100. The first semiconductor device 300 and the second semiconductor device 400 may be arranged on the substrate structure 100 to be spaced apart from each other.

The first semiconductor device 300 and the second semiconductor device 400 may be mounted on the substrate structure 100 via conductive bumps 350 and 450. First connection pads 302 of the first semiconductor device 300 may be electrically connected to the upper substrate pads 146 of the substrate structure 100 through the conductive bumps 350. Second connection pads 402 of the second semiconductor device 400 may be electrically connected to the upper substrate pads 146 of the substrate structure 100 through the conductive bumps 450. For example, the conductive bumps 350 and 450 may include micro bumps (uBumps).

For example, the first semiconductor device 300 may include a logic semiconductor device, and the second semiconductor device 400 may include a memory device. The logic semiconductor device may be an ASIC as a host such as CPU, GPU, or SoC. The memory device may include a high bandwidth memory (HBM) device. In this case, the second semiconductor device may include a buffer die 410 and a plurality of memory dies (chips) 420a, 420b, 420c, and 420d sequentially stacked on the buffer die 410. The buffer die and the memory die may be electrically connected to each other through through silicon vias (TSVs). Additionally, the second semiconductor device may further include a gap fill layer 430 that covers the memory dies on the buffer die 410.

The first semiconductor device 300 may be electrically connected to the bridge chip 200 by the conductive bump 350 that is bonded to the first bonding pad 147, and the second semiconductor device 400 may be electrically connected to the bridge chip 200 by the conductive bump 450 that is bonded the second bonding pad 148. Accordingly, the first semiconductor device 300 and the second semiconductor device 400 may be electrically connected to each other by the bridge chip 200.

In some example embodiments, first and second underfill members 360 and 460 underfilled between the first semiconductor device 300 and the substrate structure 100 and between the second semiconductor device 400 and the substrate structure 100, respectively.

The first underfill member 360 may extend between the first semiconductor device 300 and the substrate structure 100 to reinforce a gap between the first semiconductor device 300 and the substrate structure 100. The second underfill member 460 may extend between the second semiconductor device 400 and the substrate structure 100 to reinforce a gap between the second semiconductor device 400 and the substrate structure 100. Portions of the first and second underfill members 360 and 460 may extend upward from the upper surface of the substrate structure 100 to cover at least portions of outer side surfaces of the first and second semiconductor devices 300 and 400, respectively, to thereby more firmly secure the first and second semiconductor devices 300 and 400.

The first and second underfill members may include a material with relatively high fluidity to effectively fill the small spaces between the first and second semiconductor devices 300 and 400 and the substrate structure 100. For example, the first and second underfill members may include an adhesive containing an epoxy material.

In some example embodiments, the substrate structure 100 may have a first planar area, the first semiconductor device 300 may have a second planar area that is smaller than the first planar area, and the second semiconductor device 400 may have a third plane area that is smaller than the first planar area. When viewed in plan view, the first semiconductor device 300 may be disposed within the substrate structure 100. When viewed in plan view, at least a portion of the first semiconductor device 300 may overlap at least a portion of the bridge chip 200 provided in the substrate structure 100. When viewed in plan view, the second semiconductor device 400 may be disposed within the substrate structure 100. When viewed in plan view, at least a portion of the second semiconductor device 400 may overlap at least a portion of the bridge chip 200 provided within the substrate structure 100.

In some example embodiments, the external connection bumps 160 for electrical connection with an external device may be disposed on the lower substrate pads 114 on the lower surface of the substrate structure 100. For example, the external connection bump 160 may be a solder bump. For example, the solder bump may include a C4 bump. The semiconductor package 10 may be mounted on a package substrate (not illustrated) via the solder bumps to form a semiconductor module.

As mentioned above, the semiconductor package 10 may include the substrate structure 100 having the bridge chip 200 therein, the first semiconductor device 300 mounted on the substrate structure 100, and the second semiconductor device 400 mounted on the substrate structure 100 and spaced apart from the first semiconductor device 300. Because the substrate structure 100 including the redistribution wiring layer has a greater thermal expansion coefficient than the first and second semiconductor devices 300 and 400, warpage may occur due to a mismatch in thermal expansion coefficient between the substrate structure 100 and the semiconductor devices 300, 400. Because the bridge chip 200 accommodated in the substrate structure 100 includes the silicon material, the overall coefficient of thermal expansion of the substrate structure may be reduced.

The bridge chip 200 may have the convex bump structure BP in the middle region MR. The middle region MR where the bump structure BP is formed may have a relatively thick silicon portion, thereby reducing the thermal expansion coefficient of the substrate structure 100. Accordingly, the bump structure BP may increase a space ratio (concentration) occupied by the silicon die portion to match the thermal expansion coefficient between upper and lower portions of the semiconductor package, to thereby reduce or prevent the warpage.

Hereinafter, a method of manufacturing the semiconductor package of FIG. 1 will be described.

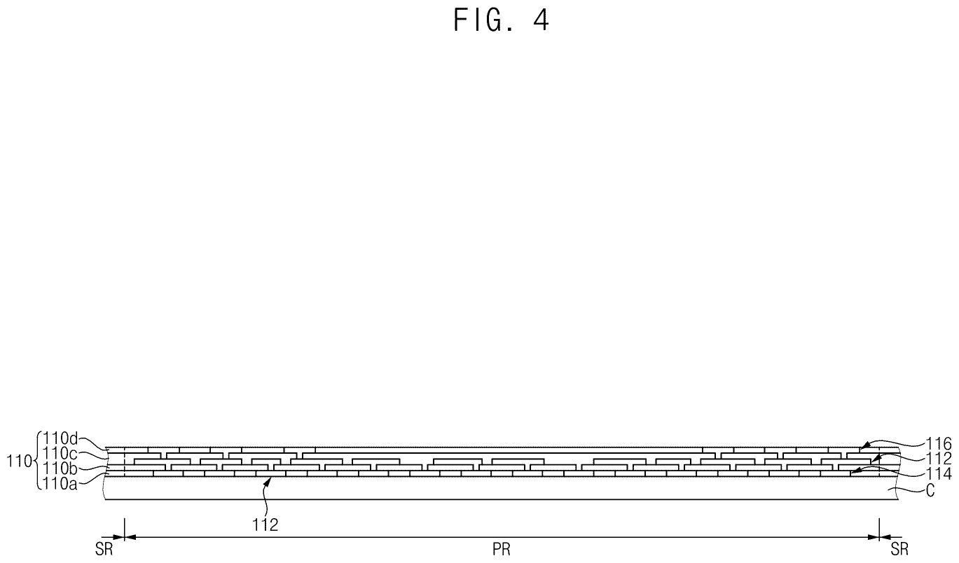

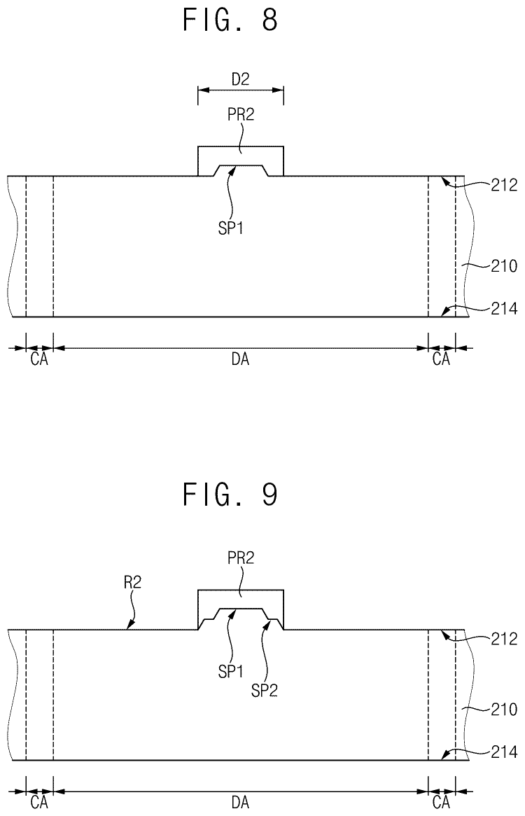

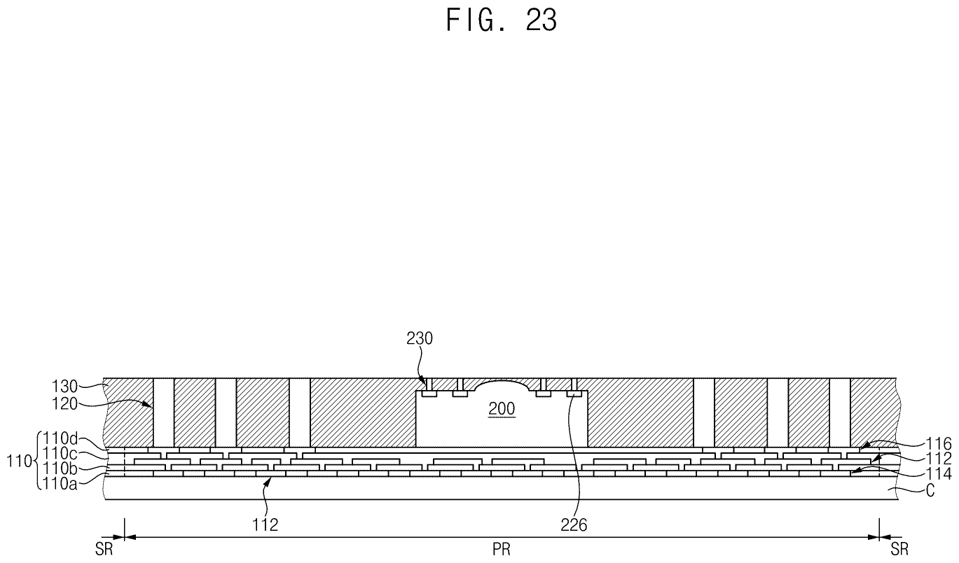

FIGS. 4 to 27 are views illustrating a method of manufacturing a semiconductor package in accordance with an example embodiment. FIGS. 4 to 8 and 10 to 12 are cross-sectional views illustrating a method of manufacturing a semiconductor package in accordance with an example embodiment. FIG. 9 is a plan view of FIG. 8. FIG. 8 is a cross-sectional view taken along the line C-C′ in FIG. 9.

Referring to FIG. 4, a lower redistribution wiring layer 110 having lower redistribution wirings 112 may be formed on a carrier substrate C.

In some example embodiments, the carrier substrate C may include a wafer substrate as a base substrate for disposing at least one bridge chip on the lower redistribution wiring layer and forming a molding member covering them. The carrier substrate C may have a shape corresponding to a wafer on which a semiconductor process is performed. For example, the carrier substrate C may include a silicon substrate, a glass substrate, a non-metallic or metallic plate, etc.

The carrier substrate C may include a package region PR on which semiconductor devices are mounted and a cutting region SR surrounding the package region PR. As will be described later, the lower redistribution wiring layer 110 and the molding member formed on the carrier substrate C may be cut along the cutting region SR that divides the plurality of package regions MR to be individualized.

In some example embodiments, a first lower insulating layer 110a having lower substrate pads 114 formed therein may be formed on the carrier substrate C. Although it is not illustrated in the figures, after a release film, a barrier metal layer, a seed layer and the first lower insulating layer are sequentially formed on the carrier substrate C, the first lower insulating layer may be patterned to form openings that expose first bonding pad regions. Then, a plating process may be performed on the seed layer to form the lower substrate pads 114 within the openings.

For example, the first lower insulating layer 110a may include a polymer, a dielectric layer, etc. The first lower insulating layer 110a may include a photosensitive insulating material such as PID or an insulating layer such as ABF. The first lower insulating layer may be formed by a spin coating process, a vapor deposition process, or the like.

The lower substrate pad 114 may be a bump pad. The bump pad may include a solder pad or pillar pad. For example, the lower substrate pad may include copper (Cu), aluminum (Al), tin (Sn), nickel (Ni), gold (Au), platinum (Pt), or an alloy thereof.

Then, after a second lower insulating layer 110b is formed on the first lower insulating layer 110a to cover the lower substrate pads 114, and then, the second lower insulating layer 110b may be patterned to form first openings that expose at least portions of the lower substrate pads 114, respectively.

Then, lower redistribution wirings 112 may be formed on the second lower insulating layer 110b to be electrically connected to the lower substrate pads 114 through the first openings, respectively.

For example, after a seed layer is formed on portions of the second lower insulating layer 140b and in the first opening, the seed layer may be patterned and an electroplating process may be performed to form the lower redistribution wirings 112. Accordingly, at least portions of the lower redistribution wirings 112 may directly contact the lower substrate pads 114 through the first openings. For example, the lower redistribution wiring may include copper (Cu), aluminum (Al), tin (Sn), nickel (Ni), gold (Au), platinum (Pt), or an alloy thereof.

In this example embodiment, the lower redistribution wiring layer having the lower redistribution wirings 112 of one layer is described, however, it is not limited thereto, and the lower redistribution wiring layer may have lower redistribution wirings stacked in at least two layers.

Then, upper connection pads 116 may be formed on the uppermost lower redistribution wirings 112.

For example, a third lower insulating layer 110c may be formed on the second lower insulating layer 110b to cover the lower redistribution wirings 112, and the third lower insulating layer 110c may be patterned to form openings that expose the lower redistribution wirings 112, respectively. The lower redistribution wirings 112 exposed by the openings may be uppermost redistribution wirings. A portion of the uppermost redistribution wiring may include a redistribution pad portion.

Then, a seed layer may be formed on the third lower insulating layer 110c, and a photoresist pattern having openings that expose upper connection pad regions may be formed on the seed layer. A plating process may be performed to form the upper connection pads 116 in the openings of the photoresist pattern. The upper connection pads may include a metal material. The upper connection pads may include the same material as the lower redistribution wirings 112. The upper connection pads may include copper (Cu). Then, after removing the photoresist pattern, portions of the seed layer exposed by the upper connection pads may be removed.

Thus, the upper connection pads 116 may be formed on the uppermost lower redistribution wirings 112 of the lower redistribution wiring layer 110. The upper connection pads 116 may be exposed from an upper surface of the lower redistribution wiring layer 110. When viewed in plan view, the lower redistribution wiring layer 110 may include a first region as a chip mounting region overlapping a bridge chip to be disposed on the lower redistribution wiring layer 110 and a second region as a connector region surrounding the first region, as will be described later. The upper connection pads 116 may be bonding pads for connection with a conductive structure, which are formed on the uppermost lower redistribution wirings 112 in the second region.

For example, the upper connection pads 116 may have a multilayer structure. The upper connection pad 116 may include a bonding pad pattern and a plating pad pattern formed on the bonding pad pattern. The bonding pad pattern may include copper (Cu), and the plating pad pattern may include nickel (Ni), gold (Au), or titanium (Ti).

Then, a fourth lower insulating layer 110d may be formed on the third lower insulating layer 110c to expose the upper connection pads 116.

It will be understood that the number, size, and arrangement of the lower insulating layers and the lower redistribution wirings of the lower redistribution wiring layer are provided as examples, and the present inventive concepts are not limited thereto.

Thus, the lower redistribution wiring layer 110 having the first to fourth lower insulating layers 110a, 110b, 110c, and 110d may be formed. The lower redistribution wiring layer 110 may be provided as a lower redistribution wiring layer of a substrate structure as an interposer. The lower redistribution wiring layer 110 may include the lower redistribution wirings 112. The lower substrate pads 114 may be exposed from a lower surface of the lower redistribution wiring layer 110. For example, a thickness of the first redistribution wiring layer 110 may be within a range of about 5 μm to about 50 μm.

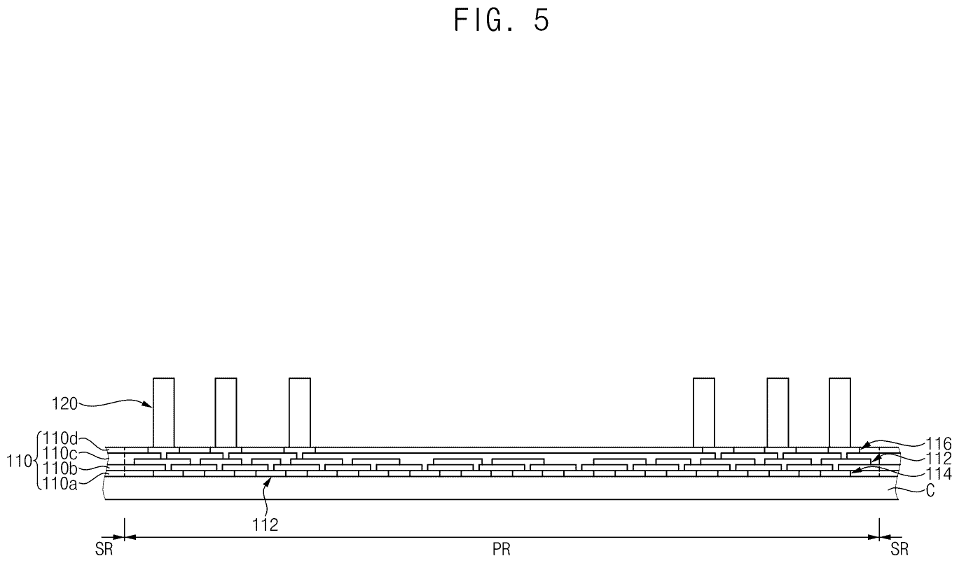

Referring to FIG. 5, vertical conductive structures 120 may be formed on the upper connection pads 116 on the upper surface of the lower redistribution wiring layer 110, respectively.

In some example embodiments, a seed layer may be formed on the upper surface of the lower redistribution wiring layer 110 to cover the upper connection pads 116, and a photoresist pattern having openings that expose vertical conductive structure regions may be formed on the seed layer. The openings may expose at least portions of the upper connection pads 116 in the second region.

Then, an electrolytic plating process may be performed on the seed layer to fill the openings of the photoresist pattern with a conductive material to form the vertical conductive structures 120. For example, the vertical conductive structures 120 may include copper (Cu). A lower end portion of the vertical conductive structure 120 may be bonded to the upper connection pad 116. Then, the photoresist pattern may be removed through a strip process.

Thus, the vertical conductive structures 120 may extend upward from the upper connection pads 116 of the lower redistribution wiring layer 110 respectively. For example, a diameter of the vertical conductive structure 120 may be in a range of about 20 μm to about 100 μm, and a length of the vertical conductive structure 120 may be in a range of about 50 μm to about 300 μm.

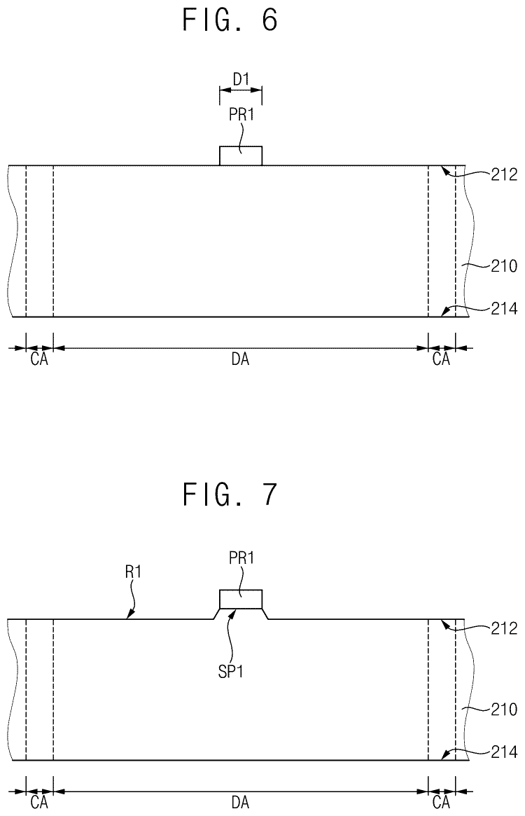

Referring to FIGS. 6 to 20, a bridge chip 200 may be formed and placed in the first region of the lower redistribution wiring layer 110.

As illustrated in FIGS. 6 to 15, a bump structure BP may be formed in a middle region MR of a substrate 210, such as a silicon wafer W, to protrude from an upper surface 212 of the substrate 210.

First, as illustrated in FIGS. 6 and 7, a first photoresist pattern PR1 having a first diameter D1 may be formed on the upper surface 212 of the substrate 210, and a silicon recess process may be performed on the upper surface 212 of the substrate 210 using the first photoresist pattern PR1 as an etching mask. Accordingly, the upper surface 212 of the substrate 210 may be partially removed to form a first recess R1 that defines a first step portion SP1. The etching process may be an isotropic dry etching process. The etching process may include a plasma etching process. The plasma etching process may be performed using inductively coupled plasma, capacitively coupled plasma, microwave plasma, etc. The first step portion SP1 may have a side wall that is inclined at a first angle with respect to the upper surface 212. The first angle of the sidewall may be determined by process conditions of the etching process.

Then, as illustrated in FIGS. 8 and 9, after the first photoresist pattern PR1 is removed, a second photoresist pattern PR2 having a second diameter D2 greater than the first diameter D1 may be formed on the upper surface 212 of the substrate 210 to cover the first step portion SP1, and a silicon recess process may be performed on the upper surface 212 of the substrate 210 using the second photoresist pattern PR2 as an etching mask. Accordingly, the upper surface 212 of the substrate 210 may be partially removed to form a second recess R2 that defines a second step portion SP2. The second step portion SP2 may have a side wall that is inclined at a second angle greater than the first angle with respect to the upper surface 212.

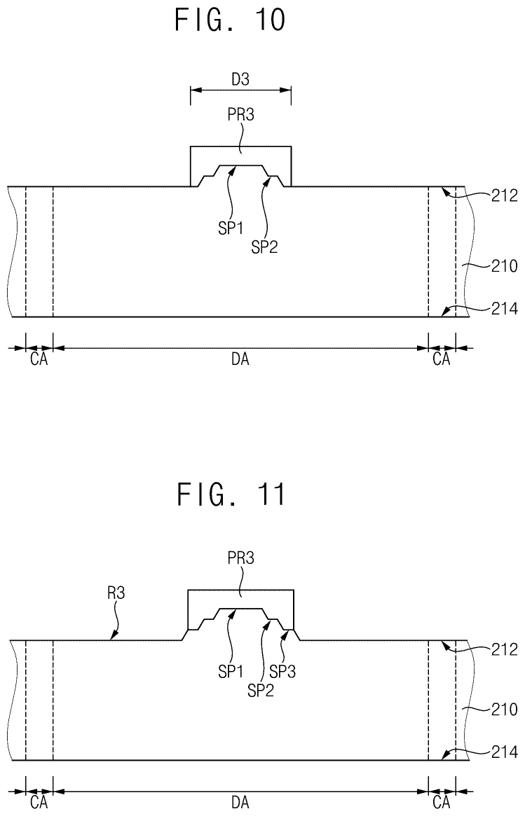

Then, as illustrated in FIGS. 10 and 11, after the second photoresist pattern PR2 is removed, a third photoresist pattern PR3 having a third diameter D3 greater than the second diameter D2 may be formed on the upper surface 212 of the substrate 210 to cover the first and second step portions SP1 and SP2, and a silicon recess process may be performed on the upper surface 212 of the substrate 210 using the third photoresist pattern PR3 as an etching mask. Accordingly, the upper surface 212 of the substrate 210 may be partially removed to form a third recess R3 that defines a third step portion SP3. The third step portion SP3 may have a side wall that is inclined at a third angle greater than the second angle with respect to the upper surface 212.

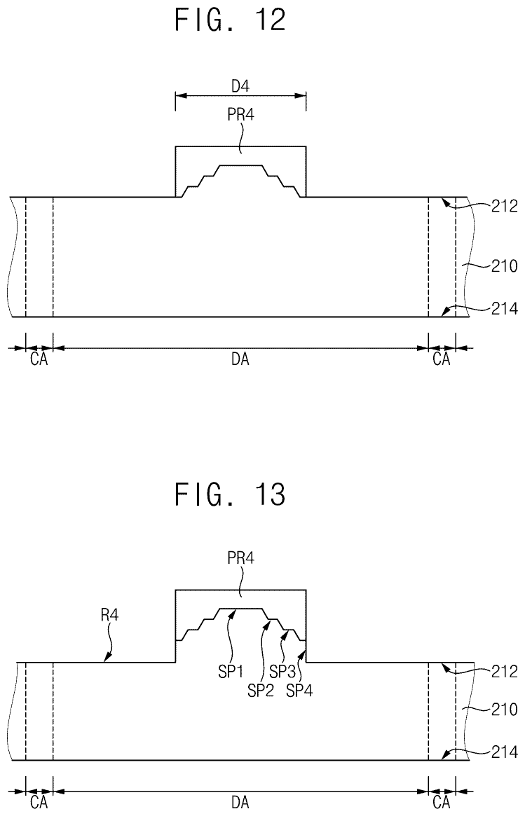

Then, as illustrated in FIGS. 12 and 13, after the third photoresist pattern PR3 is removed, a fourth photoresist pattern PR4 having a fourth diameter D4 greater than the third diameter D3 may be formed on the upper surface 212 of the substrate 210 to cover the first, second and third step portions SP1, SP2 and SP3, and a silicon recess process may be performed on the upper surface 212 of the substrate 210 using the fourth photoresist pattern PR4 as an etching mask. Accordingly, the upper surface 212 of the substrate 210 may be partially removed to form a fourth recess R4 that defines a fourth step portion SP4. The fourth step portion SP4 may have a side wall that is inclined at a fourth angle greater than the third angle with respect to the upper surface 212.

Thus, a protruding structure having the first to fourth step portions SP1, SP2, SP3, and SP4 may be formed in the middle region MR on the upper surface 212 of the substrate 210.

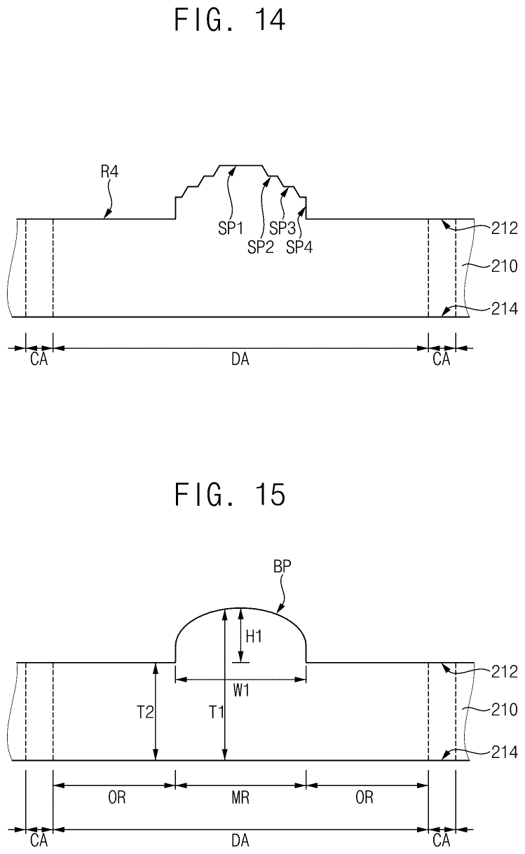

Then, as illustrated in FIGS. 14 and 15, a surface treatment may be performed on the protruding structure on the upper surface 212 of the substrate 210 to form the bump structure BP having a convex cross-section.

The substrate 210 may have the middle region MR and a peripheral region OR surrounding the middle region MR. The substrate 210 may have the bump structure BP that protrudes from the upper surface in the middle region MR. For example, the bump structure BP may have a desired (or alternatively, predetermined) height H1 from the upper surface of the substrate 210. The bump structure BP may have a desired (or alternatively, predetermined) width W1. The middle region MR of the substrate 210 may have a first thickness T1, and the peripheral region OR of the substrate 210 may have a second thickness T2. The first thickness T1 may be greater than the second thickness T2. The bump structure BP may have a dome shape. The bump structure BP may have a convex cross-sectional shape.

In this example embodiment, the bridge chip 200 includes the convex dome-shaped bump structure BP, but it is not limited to, and the bump structure protruding from the upper surface 212 of the substrate 210 may have a cylindrical shape, a square column shape, a truncated cone shape, a polygonal pyramid shape, etc.

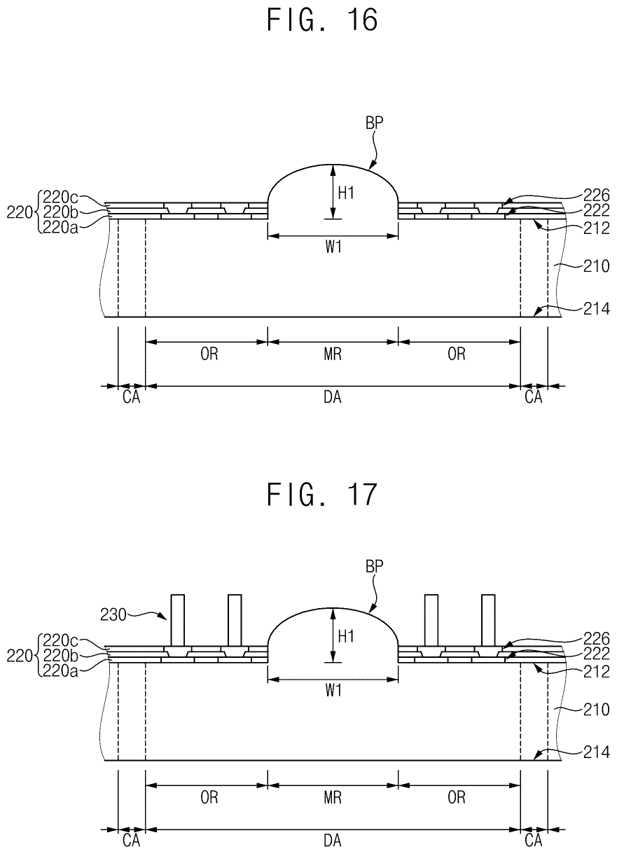

Then, as illustrated in FIGS. 16 and 17, a wiring layer 220 having a plurality of wirings 222 on the peripheral region OR around the middle region MR of the substrate 210 and bridge chip pads 226 may be formed on the wiring layer 220 to be electrically connected to the wirings 222.

For example, a first insulating layer 220a having the wirings 222 formed therein may be formed on the upper surface 212 of the substrate 210, and a second insulating layer 220b may be formed on the first insulating layer 220a to cover the wirings 222. Then, the second insulating layer 220b may be patterned to form openings that expose portions of the wirings 222, a seed layer may be formed on the second insulating layer 220b, and a photoresist pattern having openings that expose bridge chip pad regions may be formed on the seed layer. A plating process may be performed on the seed layer to form the bridge chip pads 226 within the openings of the photoresist pattern. The bridge chip pads may include a metal material. The bridge chip pads may include the same material as the wiring 222. The bridge chip pads may include copper (Cu). Then, after removing the photoresist pattern, portions of the seed layer exposed by the bridge chip pads may be removed.

Then, a third insulating layer 220c may be formed on the second insulating layer 220b to expose the bridge chip pads 222.

Thus, the wiring layer 220 may include the first, second and third insulating layers 220a, 220b, and 220c and the wirings 222 provided in the first, second and third insulating layers 220a, 220b, and 220c.

The bridge chip pads 226 may include a first bridge chip pad 226a and a second bridge chip pad 226b that are electrically connected to each other and are disposed with the bump structure BP therebetween. The first bridge chip pads 226a may be arranged in a first side of the bump structure BP to be spaced apart from each other in a first direction, and the second bridge chip pads 226a may be arranged in a second side opposite to the first side of the bump structure BP to be spaced apart from each other in the first direction. The first bridge chip pads 226a may be electrically connected to the second bridge chip pads 226b through the wires 222, respectively.

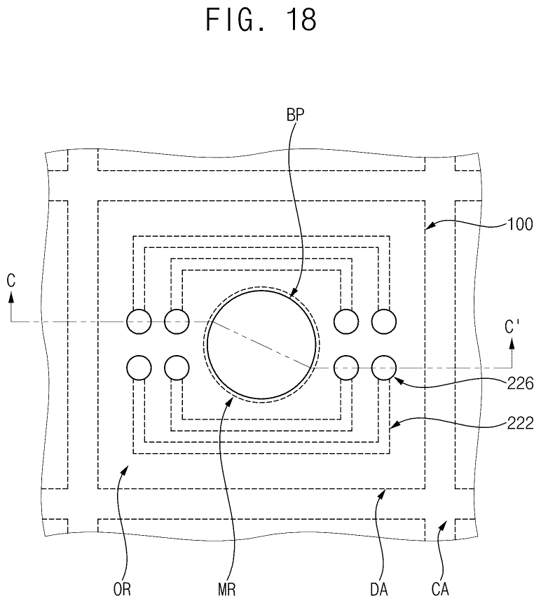

As illustrated in FIGS. 17 and 18, conductive pillars 230 may be formed on the bridge chip pads 226.

For example, a seed layer may be formed on an upper surface of the wiring layer 220 on the substrate 210 to cover the bridge chip pads 226, and a photoresist pattern having openings that expose conductive pillar regions may be formed on the seed layer. The openings may expose at least portions of the bridge chip pads 226 in the peripheral region OR. Then, an electrolytic plating process may be performed on the seed layer to fill the openings of the photoresist pattern with a conductive material to form the conductive pillars 230. For example, the conductive pillars 230 may include copper (Cu). A lower end portion of the conductive pillar 230 may be bonded to the bridge chip pad 226. Then, the photoresist pattern can be removed through a strip process.

Thus, the conductive pillars 230 may extend upward from the first and second bridge chip pads 226a and 226b of the wiring layer 220, respectively. For example, a diameter of the conductive pillar 230 may be within a range of about 10 μm to about 60 μm, and a length of the conductive pillar 230 may be within a range of about 30 μm to about 80 μm.

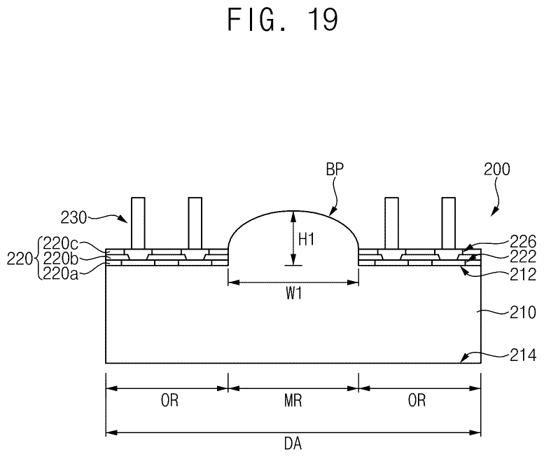

As illustrated in FIG. 19, the substrate 210 may be individually separated along the cutting region CA by a sawing process to form a plurality of bridge chips 200.

The substrate 210 may be separated such that the bridge chips 200 have a desired shape. The bridge chip 200 may have a rectangular shape with a short side in the first direction and a long side in a second direction perpendicular to the first direction.

Each of the bridge chips 200 may include the substrate 210 including a silicon material and having the bump structure BP having a convex cross-sectional shape in the middle region MR, and the wiring layer 220 having the plurality of wirings 222 on the peripheral region OR of the substrate 210, the bridge chip pads 226 on the wiring layer 220 and electrically connected to the wirings 222, and the conductive pillars 230 extending upward on the bridge chip pads 226.

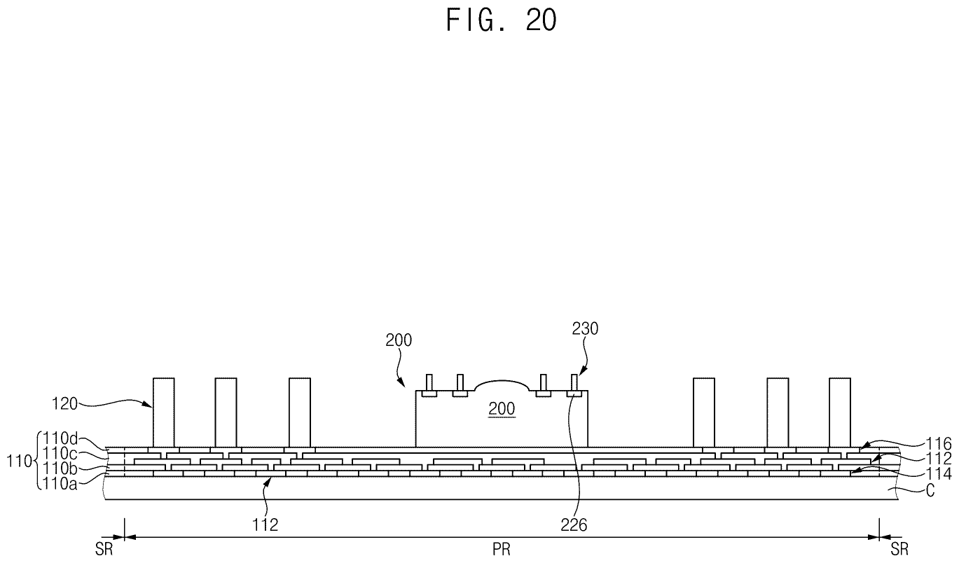

As illustrated in FIG. 20, the bridge chip 200 may be disposed on the first region on the lower redistribution wiring layer 110.

In some example embodiments, the bridge chip 200 may be attached to the upper surface of the lower redistribution wiring layer 110 using an adhesive film. The plurality of vertical conductive structures 120 may be disposed around the bridge chip 200 on the lower redistribution wiring layer 110.

In the figures, one bridge chip is disposed, but the present inventive concepts are not limited thereto. For example, bridge chips having the same number as the number of second semiconductor devices connected to a first semiconductor device may be disposed.

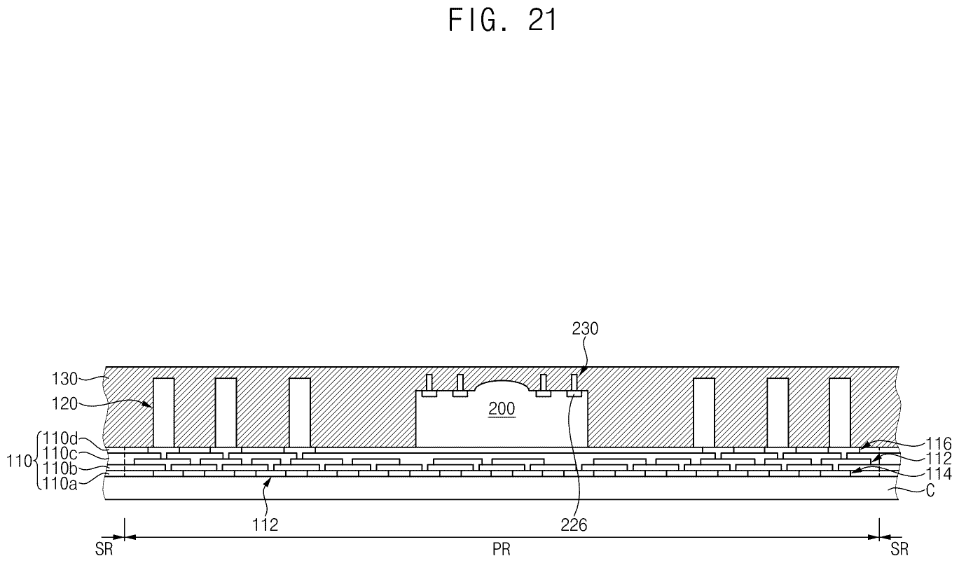

Referring to FIGS. 21 to 23, a sealing member 130 may be formed on the lower redistribution wiring layer 110 to cover the bridge chip 200 and the plurality of vertical conductive structures 120. The sealing member 130 may include a first sealing portion that covers an upper surface of the bridge chip 200 and a second sealing portion that covers the vertical conductive structures 120.

As illustrated in FIG. 21, the sealing member 130 that completely covers the bridge chip 200 and the plurality of vertical conductive structures 120 may be formed on the lower redistribution wiring layer 110.

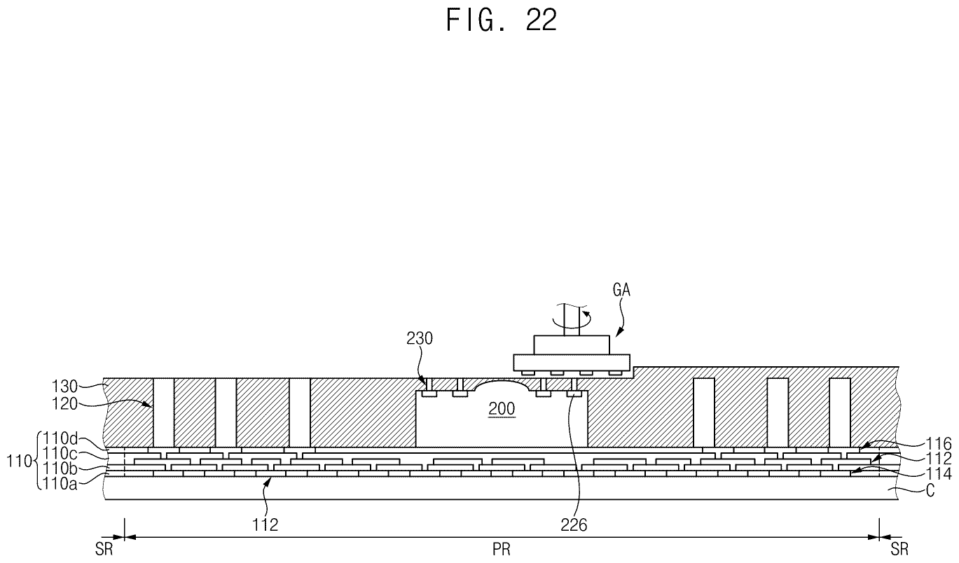

As illustrated in FIG. 22, an upper portion of the sealing member 130 may be removed using a grinding apparatus GA until upper surfaces of the conductive pillars 230 of the bridge chip 200 and the plurality of vertical conductive structures 120 are exposed. When removing the upper portion of the sealing member 130, portions of the conductive pillars 230 and portions of the vertical conductive structures 120 may be removed together.

When removing the upper portion of the sealing member 130, a relatively small portion of the sealing member 130 on the convex-shaped bump structure BP may be removed. That is, the first sealing portion of the sealing member 130 on the bridge chip 200 may have a relatively thin thickness due to the bump structure BP.

For example, the sealing member 130 may include an epoxy mold compound (EMC). The sealing member 130 may include UV resin, polyurethane resin, silicone resin, silica fillers, etc.

Because the bridge chip 200 accommodated in the sealing member 130 includes a silicon material, the bridge chip may have a relatively low coefficient of thermal expansion. The bump structure BP of the bridge chip 200 may have a first thermal expansion coefficient, and the sealing member 130 may have a second thermal expansion coefficient that is greater than the first thermal expansion coefficient.

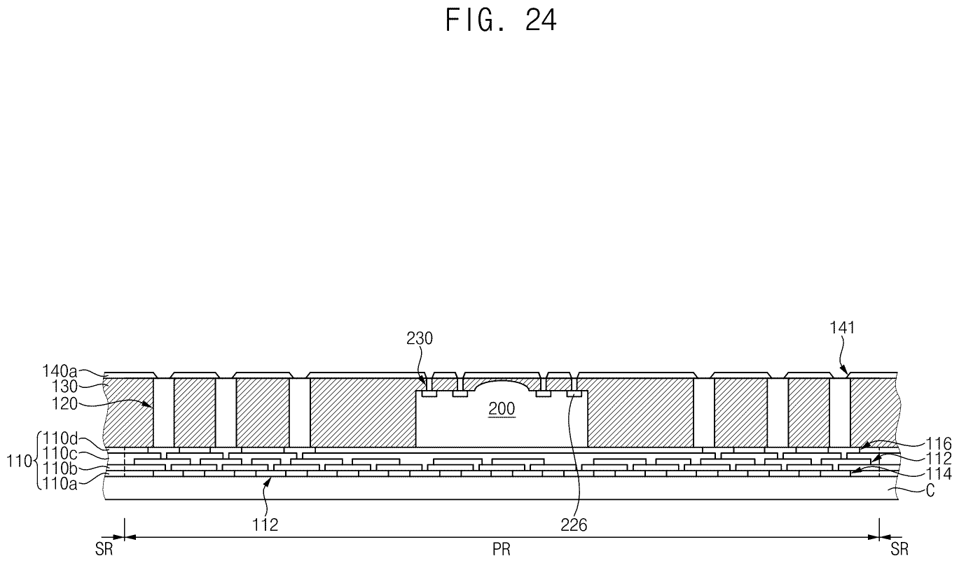

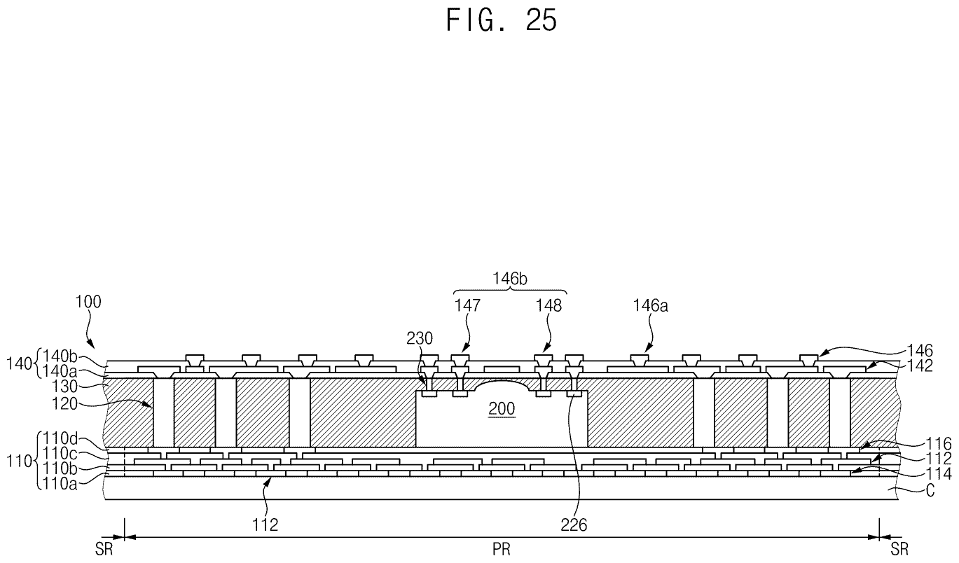

Referring to FIGS. 24 and 25, an upper redistribution wiring layer 140 having upper redistribution wirings 142 electrically connected to the plurality of vertical conductive structures 120 and the conductive pillars 230 may be formed on the sealing member 130.

As illustrated in FIG. 24, after a first upper insulating layer 140a is formed on an upper surface of the sealing member 130, the first upper insulating layer 140a may be patterned to form openings 141 that expose the upper end portions of the vertical conductive structures 120 and the upper end portion of the conductive pillars 230, respectively. The first upper insulating layer 140a may include a polymer, a dielectric layer, etc. The first upper insulating layer 140a may be formed by a vapor deposition process, spin coating process, etc.

As illustrated in FIG. 25, a seed layer may be formed on portions of the vertical conductive structures 120 and the conductive pillars 230 exposed by the openings 141 and in the openings 141, the seed layer may be patterned, and an electrolytic plating process may be performed to form the upper redistribution wirings 142. Accordingly, at least portions of the upper redistribution wirings 142 may be electrically connected to the vertical conductive structures 120 and the conductive pillars 230 through the openings 141. The upper redistribution wirings may include aluminum (Al), copper (Cu), tin (Sn), nickel (Ni), gold (Au), platinum (Pt), or an alloy thereof.

In this example embodiment, the upper redistribution wiring layer having the upper redistribution wirings 142 of one layer is described, however, it is not limited thereto, and the upper redistribution wiring layer may have upper redistribution wirings stacked in at least two layers.

Then, upper substrate pads 146 may be formed on the uppermost upper redistribution wirings 142.

For example, a second upper insulating layer 140b may be formed on the first upper insulating layer 140a to cover the upper redistribution wirings 142, and the second upper insulating layer 140b may be patterned to form openings that expose the upper redistribution wirings 142 respectively. The upper redistribution wirings 142 exposed by the openings may be uppermost redistribution wirings. A portion of the uppermost redistribution may include a redistribution pad portion.

Then, a seed layer may be formed on the second upper insulating layer 140b, and a photoresist pattern having openings that expose upper substrate pad regions may be formed on the seed layer. A plating process may be performed to form the upper substrate pads 146 within the openings of the photoresist pattern. The upper substrate pads may include a metal material. The upper substrate pads may include the same material as the upper redistribution wirings 142. The upper substrate pads may include copper (Cu). Then, after removing the photoresist pattern, portions of the seed layer exposed by the upper substrate pads may be removed.

Thus, the upper substrate pads 146 may be formed on the uppermost upper redistribution wirings 142 of the upper redistribution wiring layer 140. The upper substrate pads 146 may be exposed from an upper surface of the upper redistribution wiring layer 140. When viewed in plan view, the upper redistribution wiring layer 140 may include a third region and a fourth region that respectively overlap the first semiconductor device and the second semiconductor device disposed on the upper redistribution wiring layer 140, as will be described later. The upper substrate pads 146 may be bonding pads for connection with the semiconductor device, which are formed on the uppermost upper redistribution wirings 142 in the third and fourth regions.

For example, the upper substrate pads 146 may have a multilayer structure. The upper substrate pad 146 may include a bonding pad pattern and a plating pad pattern formed on the bonding pad pattern. The bonding pad pattern may include copper (Cu), and the plating pad pattern may include nickel (Ni), gold (Au), or titanium (Ti).

The upper substrate pads 146 may include first upper bonding pads 146a and second upper bonding pads 146b. First pads among the first upper bonding pads 146a may be pads for connection with the first semiconductor device, and second pads among the first upper bonding pads 146a may be pads for connection with the second semiconductor device. The second upper bonding pads 146b may include first bonding pads 147 and second bonding pads 148.

The first bonding pads 147 may be pads for electrical connection between the first semiconductor device and the bridge chip, and the second bonding pads 148 may be pads for electrical connection between the second semiconductor device and the bridge chip. The first bonding pad 147 may be electrically connected to the first bridge chip pad 226a by the upper redistribution wiring 142 and the conductive pillar 230, and the second bonding pad 148 may be connected to the second bridge chip pad 226b by the upper redistribution wiring 142 and the conductive pillar 230. Accordingly, the first bonding pad 147 and the second bonding pad 148 may be electrically connected to each other by the upper redistribution wiring 142 and the bridge chip 200.

It will be understood that the number, size, and arrangement of the upper insulating layers and the upper redistribution wirings of the upper redistribution wiring layer are provided as examples, and the present inventive concepts are not limited thereto.

Thus, the substrate structure 100 as an interposer having the bridge chip 200 therein may be formed. The substrate structure 100 may include the lower redistribution wiring layer 110, the bridge chip 200 disposed on the lower redistribution wiring layer 110 and having the bump structure BP, the plurality of vertical conductive structures 120 disposed around the bridge chip 200 on the lower redistribution wiring layer 110, the sealing member 130 covering the bridge chip 200 and the plurality of vertical conductive structures 120 on the lower redistribution wiring layer 110, and the upper redistribution wiring layer 140 provided on the sealing member 130.

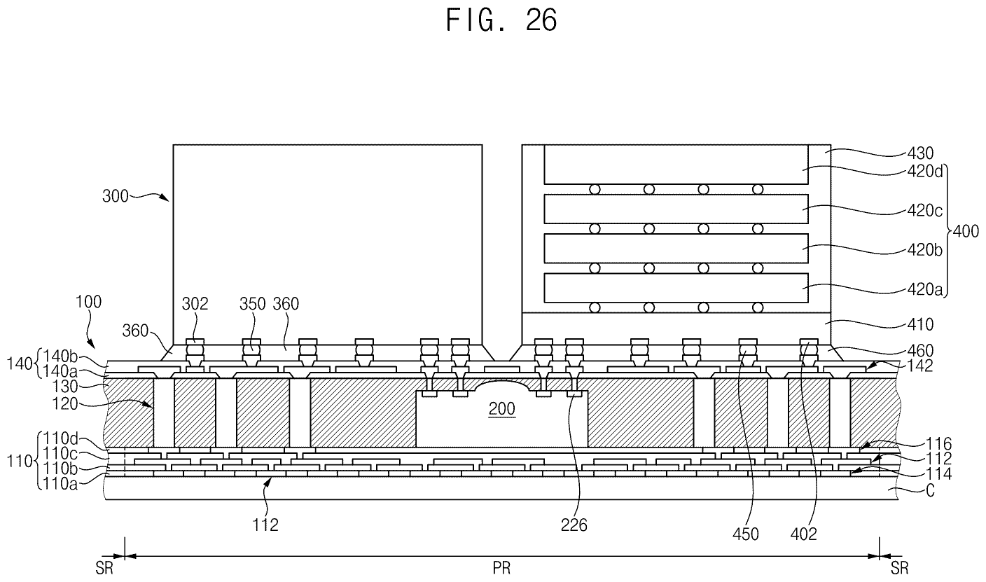

Referring to FIG. 26, a first semiconductor device 300 and a second semiconductor device 400 may be mounted on the substrate structure 100. The first and second semiconductor devices 300 and 400 may be arranged on the substrate structure 100 to be spaced apart from each other.

In some example embodiments, the first and second semiconductor devices may be mounted on the substrate structure 100 using a flip chip bonding method. First connection pads 302 of the first semiconductor device 300 may be electrically connected to the upper substrate pads 146 of the substrate structure 100 through conductive bumps 350. Second connection pads 402 of the second semiconductor device 400 may be electrically connected to the upper substrate pads 146 of the substrate structure 100 through conductive bumps 450. For example, the conductive bumps 350 and 450 may include micro bumps (uBumps).

For example, the first semiconductor device 300 may include a logic semiconductor device, and the second semiconductor device 400 may include a memory device. The logic semiconductor device may be an ASIC as a host such as CPU, GPU, or SoC. The memory device may include a high bandwidth memory (HBM) device. In this case, the second semiconductor device may include a buffer die 410 and a plurality of memory dies (chips) 420a, 420b, 420c, and 420d sequentially stacked on the buffer die 410. The buffer die and the memory die may be electrically connected to each other through through silicon vias (TSVs). Additionally, the second semiconductor device may further include a gap fill layer 430 that covers the memory dies on the buffer die 410.

The first semiconductor device 300 may be electrically connected to the bridge chip 200 by the conductive bump 350 that is bonded to the first bonding pad 147, and the second semiconductor device 400 may be electrically connected to the bridge chip 200 by the conductive bump 450 that is bonded to the second bonding pad 148. Accordingly, the first semiconductor device 300 and the second semiconductor device 400 may be electrically connected to each other by the bridge chip 200.

Then, a dispenser nozzle may be moved along edges of the first and second semiconductor devices 300 and 400 to dispense an underfill solution between the first and second semiconductor devices 300 and 400 and the substrate structure 100, and then, the underfill solution may be hardened to form first and second underfill members 360 and 460. The first underfill member 360 may extend between the first semiconductor device 300 and the substrate structure 100 to reinforce a gap between the first semiconductor device 300 and the substrate structure 100. The second underfill member 460 may extend between the second semiconductor device 400 and the substrate structure 100 to reinforce a gap between the second semiconductor device 400 and the substrate structure 100.

The first and second underfill members may include a material with relatively high fluidity to effectively fill the small space between the first and second semiconductor devices 300 and 400 and the substrate structure 100. For example, the first and second underfill members may include an adhesive containing an epoxy material.

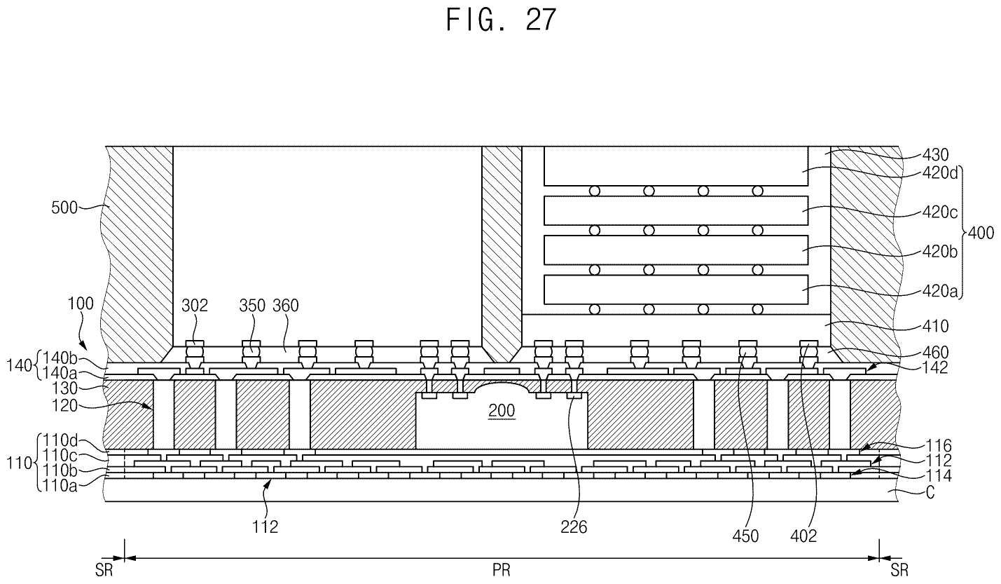

Referring to FIG. 27, a sealing member 500 may be formed on the substrate structure 100 to cover the first and second semiconductor devices 300 and 400.

In some example embodiments, the sealing member 500 may be formed on the substrate structure 100 to cover the first and second semiconductor devices 300 and 400, and then, the sealing member 500 may be partially removed to expose upper surfaces of the first and second semiconductor devices 300, 400.

Then, external connection bumps may be formed on the lower substrate pads 114 of the substrate structure 100. For example, a photoresist pattern having openings that expose the lower substrate pads 144 may be formed on the lower surface of the substrate structure 100, and the openings of the photoresist pattern may be filled up with a conductive material to form the external connection bumps. For example, the conductive material may be formed through a plating process. For example, the external connection bumps may be formed by a screen printing process, a deposition process, etc. For example, the external connection bump may include a C4 bump.

In some example embodiments, after forming the substrate structure 100 of FIG. 25, the external connection bumps may be formed on the lower substrate pads 114 of the substrate structure 100.

Then, the substrate structure 100 may be cut along the cutting region SR to complete the semiconductor package 10 of FIG. 1.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of some example embodiments and is not to be construed as limiting thereof. Although a few example embodiments have been described, those skilled in the art will readily appreciate that many modifications are possible in the disclosed example embodiments without materially departing from the novel teachings and advantages of the present inventive concepts. Accordingly, all such modifications are intended to be included within the scope of example embodiments as defined in the claims.

What is claimed is:

1. A semiconductor package, comprising:
a lower redistribution wiring layer having lower redistribution wirings;
a bridge chip on the lower redistribution wiring layer, the bridge chip including a substrate and bridge chip pads, a bump structure being an upwardly protruding portion of the substrate, the bridge chip pads being around the bump structure on the substrate;
a sealing member covering the bridge chip on the lower redistribution wiring layer;
a plurality of vertical conductive structures being around the bridge chip, penetrating the sealing member, and electrically connected to the lower redistribution wirings;
an upper redistribution wiring layer being on the sealing member, the upper redistribution wiring layer including upper redistribution wirings, the upper redistribution wirings being electrically connected to the plurality of vertical conductive structures and the bridge chip pads;
a first semiconductor device mounted on the upper redistribution wiring layer; and
a second semiconductor device mounted on the upper redistribution wiring layer and spaced apart from the first semiconductor device, the second semiconductor device being electrically connected to the first semiconductor device by the bridge chip.

2. The semiconductor package of claim 1, wherein
the substrate of the bridge chip includes a middle region and a peripheral region surrounding the middle region,
the bump structure is in the middle region of the substrate,
a wiring layer having a plurality of wirings is in the peripheral region of the substrate, and
the bridge chip pads are on the wiring layer and are electrically connected to the wirings.

3. The semiconductor package of claim 2, wherein the bridge chip pads include a first bridge chip pad and a second bridge chip pad, the bump structure is between the first bridge chip pad and the second bridge chip pad, and the first bridge chip pad and the second bridge chip pad are electrically connected to each other by the wirings.

4. The semiconductor package of claim 3, wherein the bridge chip further includes conductive pillars, and the conductive pillars are on the first bridge chip pad and the second bridge chip pad, respectively and are electrically connected to the upper redistribution wirings.

5. The semiconductor package of claim 3, wherein the upper redistribution wiring layer includes a first bonding pad electrically connected to the first bridge chip pad and a second bonding pad electrically connected to the second bridge chip pad, and
wherein the first semiconductor device is mounted via a conductive bump that is bonded to the first bonding pad, and the second semiconductor device is mounted via a conductive bump that is bonded to the second bonding pad.

6. The semiconductor package of claim 4, wherein each of the conductive pillars has a first diameter, and each of the vertical conductive structures has a second diameter, the second diameter being greater than the first diameter.

7. The semiconductor package of claim 1, wherein the bump structure has a convex cross-sectional shape.

8. The semiconductor package of claim 1, wherein the bump structure has at least one of a dome shape, a cylinder shape, a square pillar shape, a truncated cone shape, or a polygonal pyramid shape.

9. The semiconductor package of claim 1, wherein the bump structure has a first coefficient of thermal expansion and the sealing member has a second coefficient of thermal expansion, the second coefficient of thermal expansion being greater than the first coefficient of thermal expansion.

10. The semiconductor package of claim 1, wherein, when viewed in plan view, at least a portion of the first semiconductor device overlaps at least a portion of the bridge chip, and at least a portion of the second semiconductor device overlaps at least a portion of the bridge chip.

11. A semiconductor package, comprising:
an interposer including a lower redistribution wiring layer, a bridge chip, a plurality of vertical conductive structures, a sealing member, and an upper redistribution wiring layer, the bridge chip being on the lower redistribution wiring layer and including a substrate, the substrate having a bump structure in a middle region thereof, the bump structure being an upwardly protruding portion of the substrate, the plurality of vertical conductive structures being around the bridge chip on the lower redistribution wiring layer, the sealing member covering the bridge chip and the plurality of vertical conductive structures on the lower redistribution wiring layer, the upper redistribution wiring layer being on the sealing member and including upper redistribution wirings, the upper redistribution wirings electrically connected to the plurality of vertical conductive structures and the bridge chip;
a first semiconductor device mounted on the interposer and electrically connected to the bridge chip; and
a second semiconductor device mounted on the interposer, spaced apart from the first semiconductor device, and electrically connected to the bridge chip.

12. The semiconductor package of claim 11, wherein the bridge chip includes:
the substrate including a silicon material;
a wiring layer having a plurality of wirings on a peripheral region around the middle region of the substrate; and
bridge chip pads on the wiring layer and electrically connected to the wirings.

13. The semiconductor package of claim 12, wherein the bridge chip pads include a first bridge chip pad and a second bridge chip pad, and the bump structure is between the first bridge chip pad and the second bridge chip pad.

14. The semiconductor package of claim 13, wherein the bridge chip further includes conductive pillars, and the conductive pillars are on the first bridge chip pad and the second bridge chip pad, respectively, and are electrically connected to the upper redistribution wirings.

15. The semiconductor package of claim 13, wherein the upper redistribution wiring layer includes a first bonding pad electrically connected to the first bridge chip pad and a second bonding pad electrically connected to the second bridge chip pad, and
wherein the first semiconductor device is mounted via a conductive bump that is bonded to the first bonding pad, and the second semiconductor device is mounted via a conductive bump that is bonded to the second bonding pad.

16. The semiconductor package of claim 11, wherein the bump structure has a convex cross-sectional shape.

17. The semiconductor package of claim 11, wherein the bump structure has at least one of a dome shape, a cylinder shape, a square pillar shape, a truncated cone shape, or a polygonal pyramid shape.

18. The semiconductor package of claim 1, wherein the bump structure has a first coefficient of thermal expansion and the sealing member has a second coefficient of thermal expansion, the a second coefficient of thermal expansion being greater than the first coefficient of thermal expansion.

19. The semiconductor package of claim 11, wherein, when viewed in plan view, at least a portion of the first semiconductor device overlaps at least a portion of the bridge chip, and at least a portion of the second semiconductor device overlaps at least a portion of the bridge chip.

20. A semiconductor package, comprising:
a substrate structure including an upper surface and a lower surface opposite the upper surface, the substrate structure including a bridge chip therein;
a first semiconductor device mounted on the substrate structure; and
a second semiconductor device mounted on the substrate structure, spaced apart from the first semiconductor device, and electrically connected to the first semiconductor device by the bridge chip,
wherein the bridge chip includes,
a substrate having a middle region and a peripheral region surrounding the middle region, the substrate having a bump structure in the middle region thereof, the bump structure being an upwardly protruding portion of the substrate,
a wiring layer having a plurality of wirings on the peripheral region of the substrate, and
bridge chip pads being on the wiring layer and electrically connected to the wirings.
